(19) United States
(12) Patent Application Publication
(10) Pub. No.: US 2023/0069221 A1
(43) Pub. Date: Mar. 2, 2023

(54) COMPOSITION FOR RESIST UNDERLAYER FILM FORMATION, AND METHOD OF PRODUCING SEMICONDUCTOR SUBSTRATE

(71) Applicant: JSR CORPORATION, Tokyo (JP)

(72) Inventors: Tomoaki SEKO, Tokyo (JP); Tatsuya Sakai, Tokyo (JP); Kazunori Sakai, Tokyo (JP); Yusuke Anno, Tokyo (JP)

(73) Assignee: JSR CORPORATION, Tokyo (JP)

(21) Appl. No.: 17/961,611

(22) Filed: Oct. 7, 2022

Related U.S. Application Data
(63) Continuation of application No. PCT/JP2021/014642, filed on Apr. 6, 2021.

(30) Foreign Application Priority Data
Apr. 23, 2020 (JP) 2020-076549

(51) Int. Cl. G03F 7/075; G03F 7/20; G03F 7/32

(52) U.S. Cl. CPC G03F 7/0757; G03F 7/2004; G03F 7/322

(57) ABSTRACT

A composition for resist underlayer film formation, includes: a polysiloxane compound including a first structural unit represented by formula (1); and a solvent. X represents an organic group comprising at least one structure selected from the group consisting of a hydroxy group, a carbonyl group, and an ether bond; a is an integer of 1 to 3, wherein in a case in which a is no less than 2, a plurality of Xs are identical or different from each other; R¹ represents a halogen atom, a hydroxy group, or a monovalent organic group having 1 to 20 carbon atoms, wherein is a group other than X; and b is an integer of 0 to 2, wherein in a case in which b is 2, two R¹s are identical or different from each other, and wherein a sum of a and b is no greater than 3.

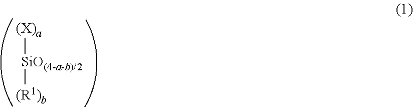

### CROSS-REFERENCE TO RELATED APPLICATIONS

The present application is a continuation application of International Application No. PCT/JP2021/014642, filed Apr. 6, 2021, which claims priority to Japanese Patent Application No. 2020-076549 filed Apr. 23, 2020. The contents of these applications are incorporated herein by reference in their entirety.

### BACKGROUND OF THE INVENTION

### Field of the Invention

The present invention relates to a composition for resist underlayer film formation, and a method of producing a semiconductor substrate.

### Discussion of the Background

In pattern anon in production of semiconductor substrates, a multilayer resist process may be employed. The multilayer resist process includes, for example: exposing and developing a resist film laminated via a resist underlayer film such as an organic underlayer film or a silicon-containing film on a substrate; and using as a mask, a resist pattern or the like thus obtained to carry out etching, whereby a substrate is formed having a pattern formed thereon (see PCT International Publication No. 2012/039337).

Recently, enhanced integration of semiconductor devices has progressed further, and in order to form a finer pattern, wavelength of exposure light for use tends to be shortened from a KrF excimer laser (248 nm), an ArF excimer laser (193 nm) or the like, to an extreme ultraviolet ray (EUV, 13.5 nm). In addition, for for ming a fine pattern, lithography may be carried out using an electron beam.

### SUMMARY OF THE INVENTION

According to an aspect of the present invention, a composition for resist underlayer film formation, includes: a polysiloxane compound comprising a first structural unit represented by formula (1); and a solvent,

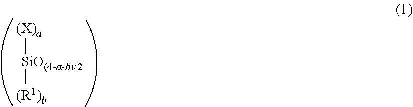

In the formula (1), X represents an organic group comprising at least one structure selected from the group consisting of a hydroxy group, a carbonyl group, and an ether bond; a is an integer of 1 to 3, wherein in a case in which a is no R¹ss than 2, a plurality of Xs are identical or different from each other; R¹ represents a halogen atom, a hydroxy group, or a monovalent organic group having 1 to 20 carbon atoms, wherein R¹ is a group other than X; and b is an integer of 0 to 2, wherein in a case in which b is 2, two R¹s are identical or different from each other, and wherein a sum of a and b is no greater than 3.

According to another aspect of the present invention, a method of producing a semiconductor substrate, includes applying a composition for resist underlayer film formation directly or indirectly on a substrate to form a resist underlayer film. A composition for metal-containing resist film formation is applied on the resist underlayer film to form a metal-containing resist film. The metal-containing resist film is exposed to an electron beam or an extreme ultraviolet ray. The exposed metal-containing resist film exposed is developed. The composition for resist underlayer film formation includes: a polysiloxane compound including a first structural unit represented by formula (1); and a solvent.

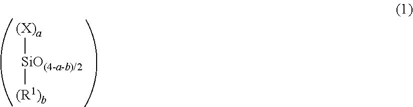

In the fon iula (1), X represents an organic group comprising at least one structure selected from the group consisting of a hydroxy group, a carbonyl group, and an ether bond; a is an integer of 1 to 3, wherein in a case in which a is no R¹ss than 2, a plurality of Xs are identical or different from each other; R¹ represents a halogen atom, a hydroxy group, or a monovalent organic group having 1 to 20 carbon atoms, wherein R¹ is a group other than X; and b is an integer of 0 to 2, wherein in a case in which b is 2, two R¹s are identical or different from each other, and wherein a sum of a and b is no greater than 3.

### DESCRIPTION OF EMBODIMENTS

As used herein, the words “a” and “an” and the like carry the meaning of “one or more.”When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4 - 7.2 as does the following list of values: 1, 4, 6, 10.

In the multilayer resist process, enabling forming a fine and metal-containing resist pattern by using a composition for forming a metal-containing resist film (hereinafter, may be also referred to as “composition for metal-containing resist film formation”) on a silicon-containing film that is a resist underlayer film is demanded. However, in conventional lithography with an electron beam or an extreme ultraviolet ray, it is difficult to form a fine and metal-containing resist pattern to have a favorable shape, with collapse of the metal-containing resist pattern being prevented. Particularly, as the resist pattern formed becomes finer, pattern collapse of the metal-containing resist pattern is more likely to occur in development and the like.

According to one aspect of the present invention made for solving the aforementioned problems, a composition for resist underlayer film formation is to be used for forming an underlayer film of a metal-containing resist film in lithography with an electron beam or an extreme ultraviolet ray, and contains: a polysiloxane compound (hereinafter, may be also referred to as “(A) compound” or “compound (A)”) having a first structural unit represented by the following formula (1); and a solvent (hereinafter, may be also referred to as “(B) solvent” or “solvent (B)”).

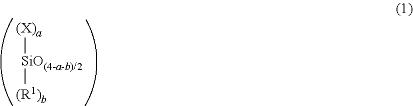

In the formula (1), X represents an organic group having at least one structure selected from a hydroxy group, a carbonyl group, and an ether bond; a is an integer of 1 to 3, wherein in a case in which a is no R¹ss than 2, a plurality of Xs are identical or different from each other; R¹ represents a halogen atom, a hydroxy group, or a monovalent organic group having 1 to 20 carbon atoms, wherein R¹ is a group other than X; and b is an integer of 0 to 2, wherein in a case in which b is 2, two R¹s are identical or different from each other, and wherein a sum of a and b is no greater than 3.

According to another aspect of the present invention made for solving the aforementioned problems, a method of producing a semiconductor substrate includes: applying a composition for resist underlayer film formation directly or indirectly on a substrate; applying a composition for metal-containing resist film formation on a resist underlayer film formed b the applying of the composition for resist underlayer film formation; exposing to an electron beam or an extreme ultraviolet ray, a metal-containing resist film formed by the applying of the composition for metal-containing resist film fon Lation, and developing the metal-containing resist film exposed, wherein the composition for resist underlayer film formation is the composition for resist underlayer film formation of the one aspect of the present invention described above.

According to the aspects of the present invention, providing: a composition for resist underlayer film formation that is to be used in forming an underlayer film of a metal-containing resist film in lithography with an electron beam or an extreme ultraviolet ray and is capable of forming a resist underlayer film that enables forming a fine and metal-containing resist pattern, with the collapse of the metal-containing resist pattern being prevented; and a method of producing a semiconductor substrate in which such a composition for resist underlayer film formation is used is enabled.

Hereinafter, the composition for resist underlayer film formation and the method of producing a semiconductor substrate of embodiments of the present invention will be described in detail.

### Composition for Resist Underlayer Film Formation

The composition for resist underlayer film fou nation of one embodiment of the present invention contains the compound (A) and the solvent (B). The composition for resist underlayer film formation may also contain other additive (hereinafter, may be also referred to as “C) additive” or “additive (C)”) aside from the compound (A) and the solvent (B), within a range not leading to impahment of the effects of the present invention.

Due to containing the compound (A) and the solvent (B), the composition for resist underlayer film formation enables forming a fine and metal-containing resist pattern in lithography with an electronbeam or an extreme ultraviolet ray, with collapse of a pattern formed on the resist underlayer film being prevented.

Since the composition for resist underlayer film formation achieves advantageous effects as described above, it can be suitably used as a composition for forming an underlayer film of a metal-containing resist film in lithography with an electron beam or an extreme ultraviolet ray.

Each component contained in the composition for resist underlayer film formation is described below.

(A) Compound

The compound (A) is a polysiloxane compound having a first structural unit represented by the following formula (1) (hereinafter, may be also referred to as “structural unit (I)”), described later. The “polysiloxane compound” as referred to herein means a compound including a siloxane bond (—Si—O—Si—). The compound (A) may also have, within a range not leading to impairment of the effects of the present invention, other structural unit(s) aside from the structural unit (I). Examples of the other structural unit include a second structural unit (hereinafter, may be also referred to as “structural unit (II)”) represented by the following formula (2) described later, a third structural unit (hereinafter, may he also referred to as “structural unit (III)”) represented by the following formula (3) described later, and the like.

Each structural unit included in the compound (A) is described below.

Structural unit (I)

The structural unit (I) is a structural unit represented by the following formula (1).

The compound (A) may have one, or two or more types of the structural unit (I).

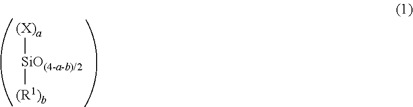

In the above formula (1), X represents an organic group having at least one structure selected from the group consisting of a hydroxy group, a carbonyl group, and an ether bond; a is an integer of 1 to 3, wherein in a case in which a is no R¹ss than 2, a plurality of Xs are identical or different from each other; R¹ represents a halogen atom, a hydroxy group, or a monovalent organic group having 1 to 20 carbon atoms, wherein R¹ is a group other than X; and b is an integer of 0 to 2, wherein in a case in which b is 2, two R¹s are identical or different from each other, and wherein a sum of a and b is no greater than 3.

As referred to herein, the “organic group” means a group having at least one carbon atom, and the number of “carbon atoms” means the number of carbon ato constituting a group.

The monovalent organic group having 1 to 20 carbon atoms which may be represented by R¹ is exemplified by: a monovalent hydrocarbon group having 1 to 20 carbon atoms; a group (hereinafter, may be also referred to as “group (a)”) that contains a divalent heteroatom-containing group between two adjacent carbon atoms of the monovalent hydrocarbon group; a group (hereinafter, may be also referred to as “group (β)”) obtained by substituting with a monovalent heteroatom-containing group, a part or all of hydrogen atoms included in the monovalent hydrocarbon group or the group (α); a group (hereinafter, may be also referred to as “group (γ)”) obtained by combining the monovalent hydrocarbon group, the group (α), or the group (β) with a divalent heteroatom-containing group; and the like. It is to be noted that the group represented by the above formula (2) is excluded from the monovalent organic group having 1 to 20 carbon atoms which may be represented by X.

As referred to herein, the “hydrocarbon group” may be exemplified by a chain hydrocarbon group, an alicyclic hydrocarbon group, and an aromatic hydrocarbon group.

The “hydrocarbon group” may be either a saturated hydrocarbon group or an unsaturated hydrocarbon group. The “chain hydrocarbon group” as referred to herein means a hydrocarbon group not including a ring structure but being constituted with only a chain structure, and may be exemplified by both a linear hydrocarbon group and a branched hydrocarbon group. The “alicyclic hydrocarbon group” as referred to herein means a hydrocarbon group including, as a ring structure, not an aromatic ring structure but an alicyclic structure alone, and may be exemplified by both a monocyclic alicyclic hydrocarbon group and a polycyclic alicyclic hydrocarbon group. With regard to this, it is not necessary for the alicyclic hydrocarbon group to be constituted with only an alicyclic structure; and it may include a chain structure in a part thereof. The “aromatic hydrocarbon group” as referred to herein means a hydrocarbon group including an aromatic ring structure as a ring structure. With regard to this, it is not necessary for the aromatic hydrocarbon group to be constituted with only an aromatic ring structure; it may include a chain structure or an alicyclic structure in a part thereof.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, an iso-butyl group, and a tert-butyl group; alkenyl groups such as an ethenyl group, a propenyl group, and a butenyl group; alkynyl groups such as an ethynyl group, a propynyl group, and a butynyl group; and the like.

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; polycyclic alicyclic unsaturated hydrocarbon groups such as a norbornenyl group, a tricyclodecenyl group, and a tet acyclododecenyl group; and the like.

Examples of the monovalent aromatic hydrocarbon group having 6 to 20 carbon atoms include: aryl groups such as a phenyl group, a tolyl group, a xylyl group, a naphthyl group, and an anthryl group; aralkyl groups such as a benzyl group, a phenethyl group, a naphthylmethyl group, and an anthrylmethyl group; and the like.

Exemplary heteroatoms which may constitute the divalentonovalent heteroatom-containing group include an oxygen atom, a nitrogen atom, a sulfur atom, a phosphorus atom, a silicon atom, a halogen atom, and the like. Examples of the halogen atom include a fluorine atom, a chlorine atom, a bromine atom,and an iodine atom.

Examples of the divalent heteroatom-containing group include —O—, —C(═O)—, —C(═S)—, —NR′—, groups obtained by combination of at least two of these, and the like, wherein R′ represents a hydrogen atom or a monovalent hydrocarbon group.

The monovalent heteroatom-containing group is exemplified by a halogen atom, a hydroxy group, a carboxy group, a cyano group, an amino group, a sulfanyl group, and the like.

Examples of the halogen atom which may be represented by R¹ include a fluorine atom, a chlorine atom, a bromine atom, and an iodine atom.

R¹ represents preferably the monovalent organic group having 1 to 20 carbon atoms, more preferably the monovalent chain hydrocarbon group, the monovalent aromatic hydrocarbon group, or the monovalent group obtained by substituting, with the monovalent heteroatom-containing group, a part or all of hydrogen atoms included in the monovalent hydrocarbon group, still more preferably the alkyl group or the aryl group, and even more preferably a methyl group, an ethyl group, or a phenyl group.

b is preferably 0 or 1, and more preferably 0.

X in the above foll iul a (1) represents an organic group having at least one structure selected from the group consisting of a hydroxy group, a carbonyl group, and an ether bond.

Examples of the organic group having a hydroxy group include hydroxyalkyl groups such as a hydroxymethyl group and a hydroxyethyl group.

The organic group having a carbonyl group is exemplified by an organic group having an ester bond, an organic group having a carbonate structure, an organic group having an amide bond, an organic group having an acyl group, an organic group having a carboxylic anhydride group, and the like.

Examples of the organic group having a carbonyl group include a group represented by the following formula (1-1), and a group represented by the following formula (1-2).

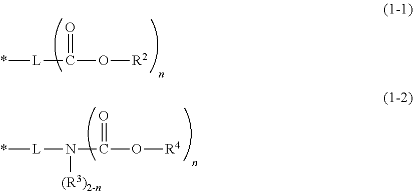

In the above formula (1-1) and), R² and R⁴ each represent a monovalent organic group having 1 to 20 carbon atoms; n is 1 or 2, wherein in a case in which n is 2, a plurality of R²s are identical or different from each other; R³ represents a hydrogen atom or a monovalent organic group having 1 to 20 carbon atoms; L represents a single bond or a divalent linking group; and * denotes a binding site to the silicon atom in the above formula (1).

Examples of the monovalent hydrocarbon group having 1 to 20 carbon atoms represented by R² or R⁴ include groups similar to the groups exemplified above as the monovalent organic group having 1 to 20 carbon atoms which may be represented by R¹, and the like.

R² and R⁴ each represent preferably the monovalent chain hydrocarbon group having 1 to 20 carbon atoms or the monovalent aromatic hydrocarbon group having 6 to 20 carbon atoms, and more preferably the monovalent chain hydrocarbon group having 1 to 20 carbon atoms.

The divalent linking group which may be represented by L is exemplified by a divalent organic group having 1 to 20 carbon atoms, and the like. Examples of the divalent organic group having 1 to 20 carbon atoms include groups obtained by removing one hydrogen atom from the monovalent organic group exemplified above as the monovalent organic group having 1 to 20 carbon atoms which may be represented b R¹, and the like.

L represents preferably a divalent hydrocarbon group having 1 to 20 carbon atoms, more preferably a divalent chain hydrocarbon group having 1 to 20 carbon atoms, and still more preferably an alkanediyl group having 1 to 20 carbon atoms. The number of carbon atoms of the group which may be represented by L is preferably 1 to 12, and more preferably 1 to 6. A preferred mode of the group represented by L may be exemplified by a group represented by —(CH₂)ₘ— (wherein in is an integer of 1 to 6).

The organic group having an ether bond which may be represented by X in the formula (1) is exemplified by organic groups having a t-butoxymethyl group, a t-butoxyethyl group, or an acetal structure.

a is preferably- 2, and more preferably 1.

Examples of the structural unit (I) include structural units derived from compounds represented by the following formulae (1-1) to (1-10), and the like.

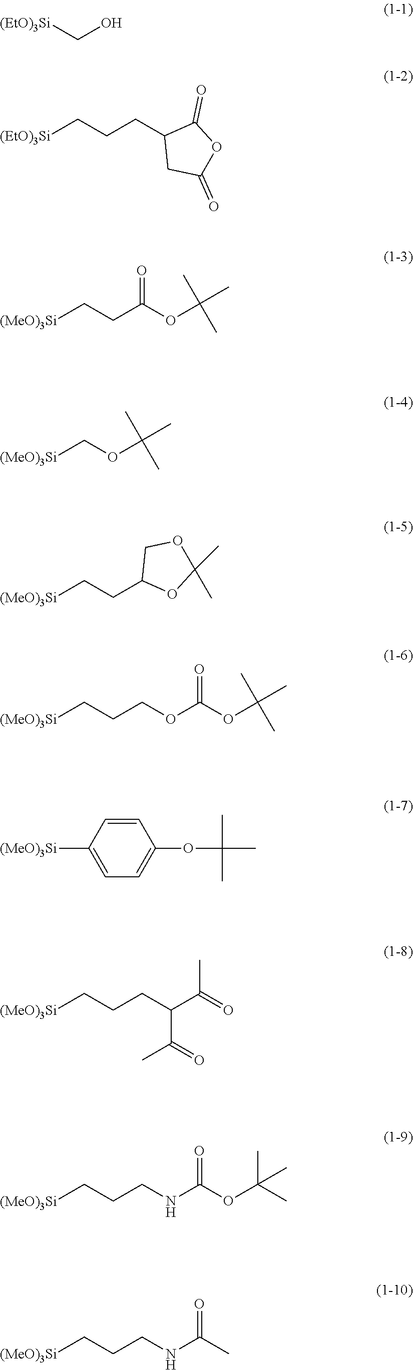

The lower limit of a proportion of the structural unit (I) contained in the compound

(A s, with respect to the total structural units constituting the compound (A), preferably 0.1 mol %, more preferably 1 mol %, still more preferably 2 mol %, and even more preferably 3 mol %. Further, the upper limit of the proportion of the structural unit (I) is preferably 80 mol %, more preferably 50 mol %, and still more preferably 20 mol %. When the proportion of the structural unit (I) falls within the above range, in forming the resist pattern on the resist underlayer film by lithography with an electron beam or extreme ultraviolet ray, a fine resist pattern with more superior rectangularity of the cross-sectional shape and with R¹ss likelihood of collapse can be formed.

Structural unit (II)

The structural unit (II) is a structural unit represented by the following formula (2). In the case in which the compound (A) has the structural unit (II), resistance to etching with oxygen gas of the resist underlayer film formed from the composition for resist underlayer film formation can be improved. The compound (A) may have one, or two or more types of the structural Unit (II).

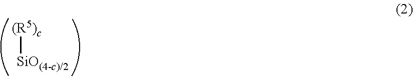

In the above formula (2), R⁵ represents a halogen atom, a hydroxy group, or a substituted or unsubstituted monovalent alkoxy group having 1 to 20 carbon atoms; and c is an integer of 0 to 3, wherein in a case in which c is no R¹ss than 2, a plurality of R⁵s are identical or different.

Examples of the substituted or unsubstituted monovalent alkoxy group having 1 to 20 carbon atoms which may be represented b R⁵ include a methoxy group, an ethoxy group, a propoxy group, and the like.

Examples of the halogen atom which may be represented by R⁵ include a fluorine atom, a chlorine atom, a bromine atom, and an iodine atom

R⁵ represents preferably the substituted or unsubstituted monovalent alkoxy group having 1 to 20 carbon atoms, and more preferably a methoxy group or an ethoxy group.

c is preferably 1 or 2.

In the case in which the compound (A) has the structural unit (TO as the other structural unit, the lower limit of a proportion of the structural unit (11) with respect to the total structural units constituting the compound (A) is preferably 30 mol %, more preferably 40 mol %, and may be still more preferably 50 mol %, 60 mol %, or 70 mol %. The upper limit of the proportion is preferably 95 mol %, more preferably 90 mol %, and still more preferably 85 mol %.

Structural Unit (III)

The structural unit (iii) is a structural unit represented by the following formula (3). In the case in which the compound (A) has the structural unit storage stability and coating characteristics of the composition for resist underlayer film formation can be improved. The compound (A) may have one, or two or more types of the structural unit (III).

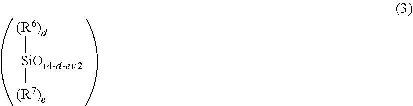

In the above formula (3), R⁶ represents a substituted or unsubstituted monovalent hydrocarbon group having 1 to 20 carbon atoms; d is an integer of 1 to 3, wherein in a case in which d is 2, two R⁶s are identical or different; R⁷ represents a halogen atom, a hydroxy uroup, or a substituted or unsubstituted monovalent organic group having 1 to 20 carbon atoms; and e is an integer of 0 to 2, wherein in a case in which e is greater than 1, a plurality of R³s are identical or different, and wherein a sum of d and e is no greater than 3.

Examples of the substituted or unsubstituted monovalent hydrocarbon group having 1 to 20 carbon atoms represented by R⁶ include groups similar to the groups exemplified above as the monovalent hydrocarbon group having 1 to 20 carbon atoms which may be represented by R¹, and the like.

d is preferably 1.

Examples of the halogen atom which may be represented by R⁷ include a fluorine atom, a chlorine atom, a bromine atom, and an iodine atom.

R⁷ represents preferably a substituted or unsubstituted monovalent alkoxy group having 1 to 20 carbon atoms, and more preferably a methoxy group or an ethoxy group.

e is preferably 0 or 1,

In the case in which the compound (A) has the structural unit (III) as the other structural unit, the lower limit of a proportion of the structural unit (III) with respect to the total structural units constituting the compound (A) is preferably 0.1 mol %, more preferably 1 mol %, and may be still more preferably 2 mol %, 3 mol %, or 5 mol %. The upper limit of the proportion is preferably 40 mol %, more preferabl 30 mol %, and still more preferabl 20 mol %.

The lower limit of a total proportion of the structural unit (I), the structural unit (II), and the structural unit (III) with respect to the total structural units constituting the compound (A) is preferabl 80 mol %, more preferably 90 mol %, and may be still more preferabl 95 mol % or 99 mol %. The upper limit of the total proportion may be 100 mol %.

The lower limit of a proportion of the compound (A) contained in composition for resist underlayer film formation with respect to total components contained in the composition for resist underlayer film formation is preferably 0.1% by mass, more preferably 0.3% by mass, and still more preferably 0.5% by mass. The upper limit of the proportion is preferably 10% by mass, more preferably 5% by mass, still more preferably 3% by mass, and even more preferabl 2% by mass.

The compound (A) preferably has a form of a polymer. A “polymer” as referred to herein means a compound having no R¹ss than two structural units; in a case in which an identical structural unit repeats twice or more, this structural unit may be also referred to as a “repeating unit.” In the case in which the compound (A) has the form of a polymer, the lower limit of a polystyrene equivalent weight average molecular weight (Mw) of the compound (A) as determined by gel permeation chromatography (GPC) is preferably 1,000, more preferably 1,200, and still more preferably 1,500. The upper limit of the Mw is preferably 10,000, more preferably 5,000, and still more preferably 3,000.

It is to be noted that as referred to herein, the Mw of the compound (A) is a value measured by gel permeation chromatography (GPC) using GPC columns available from Tosoh Corporation (“G2000 HXL”×2, “G3000 HXL”×1, and “G4000 HXL”×1) under the following conditions.

elution solvent: tetrahydrofuran

flow rate: 1.0 mL/min

sample concentration: 1.0% by mass

amount of injected sample: 100 μL

column temperature: 40° C.

detector: differential refractometer

standard substance: mono-dispersed polystyrene

The compound (A) can be synthesized by using a monomer that gives each structural unit according to a common procedure. For example, the compound (A) can be obtained by: carrying out hydrolytic condensation with a monomer that gives the structural unit (I) and, as necessary, monomer(s) that give(s) the other structural unit(s), in a solvent in the presence of water and a catalyst such as oxalic acid. It is believed that by the hydrolytic condensation reaction or the like, respective monomers are incorporated into the compound (A) regardless of a type thereof. Thus, proportions of the structural unit (I) and the other structural unit(s) in the thus synthesized compound (A) will typically be equivalent to proportions of the charge amounts of respective monomers used in a synthesis reaction.

(B) Solvent

The solvent (B) is not particularly limited and is exemplified by an alcohol solvent, a ketone solvent, an ether solvent, an ester solvent, a nitrogen-containing solvent, and the like. The solvent (B) is typically an organic solvent. The composition for resist underlayer film fol Illation may contain one, or two or more types of the solvent (:13).

Examples of the alcohol solvent include: monohydric alcohol solvents such as methanol, ethanol, n-propanol, iso-propanol, n-butanol, and iso-butanol; polyhydric alcohol solvents such as ethylene glycol, 1,2-propylene glycol, diethylene glycol, and dipropylene glycol; and the like.

Examples of the ketone solvent include acetone, methyl ethyl ketone, methyl n-propyl ketone, methyl iso-butyl ketone, cyclohexanone, 2-heptanone, and the like.

Examples of the ether solvent include ethyl ether, isopropyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran, and the like.

Examples of the ester solvent include ethyl acetate, y-butyrolactone, n-butyl acetate, ethylene glycol monomethyl ether acetate, ethylene glycol monoethyl ether acetate, diethylene glycol monomethyl ether acetate, di ethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate, and the like.

Examples of the nitrogen-containing solvent include N,N-dimethylformamide, N,N-dimethylacetamide, N-methylpyrrolidone, and the like.

Of these, the ether solvent or the ester solvent is preferred, and due to superiority in film formability, the ether solvent having a glycol structure or the ester solvent having a glycol structure is more preferred.

Examples of the ether solvent having a glycol structure and the ester solvent having a glycol structure include propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, and the like. Of these, propylene glycol monomethyl ether acetate and propylene glycol monoethyl ether are preferred.

The lower limit of a proportion of the solvent (B) contained in the composition for resist underlayer film formation with respect to the total components contained in the composition for resist underlayer film formation is preferably 90% by mass, more preferably 92.5% by mass, and still more preferably 95% by mass. The upper limit of the proportion is preferably 99.9% by mass, more preferably 99.5% by mass, and still more preferably 99% by mass.

(C) Additive(s)

The additive (C) is exemplified by an acid generating agent, a basic compound (including a base generating agent), a radical generating agent, a surfactant, colloidal silica, colloidal alumina, an organic polymer, water, and the like. The composition for resist underlayer film formation may contain one, or two or more types of the additive (C).

In the case in which the composition for resist underlayer film formation contains the additive (C), the proportion of the additive (C) contained in the composition for resist underlayer film formation may be appropriately determined in accordance with the type of the additive (C) used, and to fall within a range not leading to impairment of the effects of the present invention.

### Preparation Procedure of Composition for Resist Underlayer Film Formation

A procedure of preparing the composition for resist underlayer film formation is not particularly limited, and the composition for resist underlayer film formation may be prepared according to a common procedure. The composition for resist underlayer film formation may be prepared by, for example: mixing at a predetermined ratio, a solution of the compound (A), the solvent (B), and as needed, the additive (C); and preferably filtering a resulting mixture through a filter, etc. having a pore size of no greater than 0.2 μm.

### Method of Producing Semiconductor Substrate

The method of producing a semiconductor substrate (hereinafter, may be also referred to as “production method”) of another embodiment of the present invention includes: a step (hereinafter, may be also referred to as “composition for resist underlayer film formation-applying step”) of applying a composition for resist underlayer film formation directly or indirectly on a substrate; a step (hereinafter, may be also referred to as “composition for metal-containing resist film formation-applying step”) of applying a composition for metal-containing resist film formation directly or indirectly on a resist underlayer film formed by the composition for resist underlayer film foil ation-applying step; a step (;hereinafter, may he also referred to as “exposing step”) of exposing to an electron beam or extreme ultraviolet ray a metal-containing resist film formed by the composition for metal-containing resist film fointation-applying, step; and a step (hereinafter, may be also referred to as “development step”) of developing the metal-containing resist film exposed. In the method of producing a semiconductor substrate, the aforementioned composition for resist underlayer film formation of the one embodiment of the present invention is used as the composition for resist underlayer film faimation.

The method of producing a semiconductor substrate may further include, as needed, a step (hereinafter, may be also referred to as “heating step”) of heating a coating film formed by the composition for resist underlayer film formation-applying step, after the composition for resist underlayer film formation-applying step and before the composition for metal-containing resist film formation-applying step.

The method of producing a semiconductor substrate may further include, as needed, a step (hereinafter, may be also referred to as “organic underlayer film-forming step”) of forming an organic underlayer film directly or indirectly on the substrate, before the composition for resist underlayer film formation-applying step.

In addition, the method of producing a semiconductor substrate may further include after the development step, a step (hereinafter, may be also referred to as “etching step”) of carrying out etching using as a mask, a resist pattern formed or the like. By this etching step, a fine pattern is formed on the substrate per se.

According to the method of producing a semiconductor substrate, due to the composition for resist underlayer film formation of the aforementioned one embodiment being used for forming the resist underlayer film and due to carrying out exposing with an electron beam or extreme ultraviolet ray, foaming a fine resist pattern on the resist underlayer film is enabled. Therefore, the method of producing a semiconductor substrate enables efficient production of a semiconductor substrate having a fine pattern formed thereon. It is to be noted that the “semiconductor substrate” in the production method as referred to herein means a substrate to be used in a semiconductor device (semiconductor element), and is not limited to a substrate, a material thereof being a semiconduct.

With respect to a size of the resist pattern and substrate pattern (a pattern formed on the substrate) formed in the production method, for example, a part having a line width of no greater than 100 nm, no greater than 50 nm, no greater than 30 nm, no greater than 20 nm, or no greater than 15 nm is preferably included. A minimum line width of the resist pattern formed may be, for example, 2 nm, 5 nm, or 10 nm.

Hereinafter, each step included in thod of producing a semiconductor substrate will be described.

Organic Underlayer Film-Forming Step

In this step, before the composition for resist underlayer film formation-applying step described later, an organic underlayer film is formed directly or indirectly on the substrate described later. This step is an optional step. By this step, the organic underlayer film is formed directly or indirectly on the substrate. It is to be noted that the expression “before the composition for resist underlayer film formation-applying step” as referred to herein means not only immediately before the composition for resist underlayer film formation-applying step, but any time point upstream of the composition for resist underlayer film formation-applying step. Therefore, other optional step(s) may be included between this organic underlayer film-forming step and the composition for resist underlayer film formation-applying step.

The organic underlayer film can be formed by, for example, applying a composition for organic underlayer film formation, or the like. A procedure of forming the organic underlayer film by applying the composition for organic underlayer film formation is exemplified by a procedure of applying the composition for organic underlayer film formation directly or indirectly on the substrate to form a coating film; and hardening the coating film by subjecting the coating film to an exposure and/or heating. Examples of the composition for organic underlayer film formation include “HM8006,” available from JSR Corporation, and the like. Conditions for the heating and/or the exposure may be appropriately predetermined in accordance with the type, etc., of the composition for organic underlayer film formation employed.

The case of forming the organic underlayer film indirectly on the substrate may be exemplified by a case of forming the organic underlayer film on a low-dielectric insulating film formed on the substrate, and the like.

Composition for Resist Underlayer Film Formation-Applying Step

In this step, a composition for resist underlayer film formation is applied directly or indirectly on a substrate. By this step, a coating film of the composition for resist underlayer film formation is formed directly or indirectly on the substrate. In this step, the aforementioned composition for resist underlayer film formation of the one embodiment of the present invention is used as the composition for resist underlayer film formation.

The substrate is exemplified by insulating films of silicon oxide, silicon nitride, silicon oxynitride, polysiloxane, or the like; resin substrates; and the like. Furtheiniore, as the substrate, a substrate having a pattern formed thereon with wiring grooves (trenches), plug grooves (vias), or the like may be used.

A procedure for applying the composition for resist underlayer film formation is not particularly limited, and for example, spin-coating or the like may be exemplified.

The case of applying the composition for resist underlayer film formation indirectly on the substrate may be exemplified by a case in which the composition for resist underlayer film formation is applied on an other film formed on the substrate, and the like. The other film formed on the substrate is exemplified by an organic underlayer film, an antireflective film, or a low-dielectric insulating film, each formed by the organic underlayer film-forming step, as described above, and the like.

Heating Step

In this step, after the composition for resist underlayer film formation-applying step and before the composition for metal-containing resist film formation-applying step described later, the coating film formed by the composition for resist underlayer film formation-applying step is heated. By thus heating, the resist underlayer film is founed through hardening of the coating film, and the like.

The atmosphere in which the coating film is subjected to heating is not particularly limited, and may be, for example, an ambient air, a nitrogen atmosphere, or the like. In general, the coating film is subjected to heating in the ambient air. Various conditions such as a heating temperature and a heating time period in subjecting the coating film to heating may be predetermined appropriately. The lower limit of the heating temperature may be, for example, 150° C., and is preferably 200° C., and more preferably 210° C. or 220° C. When the heating temperature is no R¹ss than the lower limit, the amino groups can be sufficiently generated. The upper limit of the heating temperature is preferably 550° C., more preferably 450° C., and still more preferably 300° C. The lower limit of the heating time period is preferably 15 sec, and more preferably 30 sec. The upper limit of the heating time period is preferably 1,200 sec, and more preferably 600 sec.

In a case in which the composition for resist underlayer film formation contains the acid generating agent as the additive (C) and this acid generating agent is an acid generating agent that generates an acid upon an exposure, formation of the resist underlayer film may be promoted through a combination of an exposure and heating. Alternatively, in a case in which the acid generating agent is an acid generating agent that generates an acid upon heating, the heat leads to acid generation and enables the hardening reaction to be promoted.

The lower limit of an average thickness of the resist underlayer film to be formed by this step is preferably 1 nm, more preferably 3 nm, and still more preferably 5 nm. The upper limit of the average thickness is preferably 300 nm, more preferably 100 nm, still more preferably 50 nm, and even more preferably 20 nm.

Composition for Metal-Containing Resist Film Formation-Applying Step

In this step, a composition for metal-containing resist film formation is applied directly or indirectly on a resist underlayer film formed by the step(s) described above. By this composition for metal-containing resist film formation-applying step, the resist film is formed directly or indirectly on the resist underlayer film.

A procedure for applying the composition for metal-containing resist film formation is not particularly limited, and for example, spin-coating or the like may be exemplified.

In more detail with regard to this step, for example, the metal-containing resist film is formed by: applying the resist composition such that a resultant metal-containing resist film has a predetermined thickness; and thereafter subjecting the resist composition to prebaking (hereinafter, may be also referred to as “PB”) to evaporate the solvent in the coating film.

A PB temperature and a PB time period may be appropriately predetermined in accordance with the type and the like of the composition for metal-containing resist film formation employed. The lower limit of the PB temperature is preferably 30° C., and more preferably 50° C. The upper limit of the PB temperature is preferably 200° C., and more preferably 150° C. The lower limit of the PB time period is preferably 10 sec, and more preferably 30 sec. The upper limit of the PB time period is preferably 600 sec, and more preferably 300 sec.

As the composition for metal-containing resist film formation to be used in this step, a composition for metal-containing resist film formation that contains a compound having a metal atom (hereinafter, may be also referred to as “(P) metal-containing compound” or “metal-containing compound (P)”), and the like may be exemplified.

Composition for Metal-Containing Resist Film Formation

The composition for metal-containing resist film formation contains the metal-containing compound (P) in a content of no R¹ss than 50% by mass in terms of a solid content equivalent. The composition for metal-containing resist film formation preferably further contains a solvent (Q), and may further contain other component(s). When the composition for metal-containing resist film formation contains the metal-containing compound (P) in a content of no R¹ss than 50% by mass in terms of the solid content equivalent, a resist film superior in etching resistance can be formed.

(P) Metal-Containing Compound

The metal-containing compound (P) is a compound that contains a metal atom The metal-containing compound (P) may be used either alone of one type, or in a combination of two or more types thereof. Furthermore, the metal atom constituting the metal-containing compound (P) may be used either alone of one type, or in a combination of two or more types thereof. The “metal atom” as referred to herein means a concept involving metalloids, i.e., boron, silicon, germanium, arsenic, antimony, and tellurium.

The metal atom constituting the metal-containing compound (P) is not particularly limited, and for example, metal atoms from group 3 to group 16, and the like are exemplified. Specific examples of the metal atom include: metal atoms from group 4 such as a titanium atom, a zirconium atom, and a hafnium atom; metal atoms from group 5 such as a tantalum atom; metal atoms from group 6 such as a chromium atom and a tungsten atom; metal atoms from group 8 such as an iron atom and a ruthenium atom; metal atoms from group 9 such as a cobalt atom; metal atoms from group 10 such as a nickel atom; metal atoms from group 11. such as a copper atom; metal atoms from group 12 such as a zinc atom, a cadmium atom, and a mercury atom; metal atoms from group 13 such as a boron atom, an aluminum atom, a gallium atom, an indium atom, and a thallium atom; metal atoms from group 14 such as a germanium atom, a tin atom, and a lead atom; metal atoms from group 15 such as an antimony atom and a bismuth atom; metal atoms from group 16 such as a tellurium atom; and the like.

The metal atom constituting the metal-containing compound (p) preferably involves a first metal atom belonging to group 4, group 12, or group 14, and belonging to period 4, period 5, or period 6 in periodic table. In other words, the metal atom may involve at least one of titanium, zirconium, hafnium, zinc, cadmium, mercury, germanium, tin, and lead. Due to the metal-containing compound (P) thus containing the first metal atom, release of a secondary electron in a light-exposed region of the resist film, and/or a change of solubility of the metal-containing compound (P) in a developer solution by way of the secondary electron, etc., may be further promoted. As a result, pattern collapse can be certainly inhibited. The first metal atom is preferably a tin atom. or a zirconium. atom.

The metal-containing compound (P) preferably further has other atom(s) aside from the metal atom. Examples of the other atom include a carbon atom, a hydrogen atom, an oxygen atom, a nitrogen atom, a phosphorus atom, a sulfur atom, a halogen atom, and the like. Of these, a carbon atom, a hydrogen atom, and an oxygen atom are preferred. The other atom(s) in the metal-containing compound (P) may be used either alone of one type, or in a combination of two or more types thereof.

The lower limit of a content in terms of solid content equivalent of the metal-containing compound (P) in the composition for metal-containing resist film formation is preferably 70% by mass, more preferably 90% by mass, and still more preferably 95% by mass. Alternatively, the content may be 100% by mass. As referred to herein, the “solid content” in the composition for metal-containing resist film formation means components other than the solvent (Q) described later.

Procedure of Synthesizing Metal-Containing Compound (P)

The metal-containing compound (P) can be obtained by a procedure of, for example, subjecting: a metal atom and a metal compound having a hydrolyzable group; a hydrolyzate of the metal compound; a hydrolytic condensation product of the metal compound; or a combination of the same, to a hydrolytic condensation reaction, a ligand substitution reaction, or the like. The metal compound may be used either alone of one type, or in a combination of two or more types thereof.

The metal-containing compound (P) is preferably derived from a metal compound (hereinafter, may be also referred to as “metal compound (1)”) represented by the following formula (4), having a metal atom and a hydrolyzable group. By using such a metal compound (1), a stable metal-containing compound (P) can be obtained.

L¹ₐ₁MY_{b1} (4)

In the above formula (4), M represents a metal atom; L¹ represents a ligand or a monovalent organic group having 1 to 20 carbon atoms; al is an integer of 0 to 6, wherein in a case in Inch al is no R¹ss than 2, a plurality of L¹s may be identical or different; Y represents a monovalent hydrolyzable group; and bl is an integer of 2 to 6, and wherein a plurality of Ys may be identical or different. It is to be noted that L¹ represents the ligand or organic group which does not each fall under the category of Y.

The metal atom represented by M is preferably the first metal atom, and more preferably a tin atom

The hydrolyzable group represented by Y can be appropriately altered in accordance with the metal atom represented by M, and is exemplified by a substituted or unsubstituted ethynyl group, a halogen atom, an alkoxy group, an acyloxy group, a substituted or unsubstituted amino group, and the like.

A substituent in the substituted or unsubstituted ethynyl group, or the substituted or unsubstituted amino group, which may be each represented by Y, is preferably a monovalent hydrocarbon group having 1 to 20 carbon atoms, more preferably a monovalent chain hydrocarbon group having 1 to 20 carbon atoms, and still more preferably an alkyl group.

Examples of the halogen atom which may be represented by Y include a fluorine atom, a chlorine atom, a bromine atom, an iodine atom; and the like. Of these, a chlorine atom is preferred.

Examples of the alkoxy group which may be represented by Y include a methoxy group, an ethoxy group, an n-propoxy group, an i-propoxy group, an n-butoxy group, and the like. Of these, an ethoxy group, an i-propoxy group, and an n-butoxy group are preferred.

Examples of the acyloxy group which may be represented by Y include a formyl group, an acetoxy group, an ethylyloxy group, a propionyloxy group, an n-butyryloxy group, a t-butytyloxy group, a t-amylyloxy group, an n-hexanecarbonyloxy group, an n-octanecarbonyloxy group, and the like. Of these, an acetoxy group is preferred.

Examples of the substituted or unsubstituted amino group which may be represented by Y include an amino group, a methyl amino group, a dimethylamino group, a diethylamino group, a dipropylamino group, and the like. Of these, a dimethylamino group and a diethylamino group are preferred.

Suitable combinations of the metal atom represented by M and the hydrolyzable group represented by Y are described below. In the case in which the metal atom represented by M is a tin atom, the hydrolyzable group represented by Y is preferabl substituted or unsubstituted ethynyl group, the halogen atom, the alkoxy group, the acyloxy group, or the substituted or unsubstituted amino group, and more preferably the halogen atom. In the case in which the metal atom represented by M is a germanium atom, the hydrolyzable group represented by Y is preferably the halogen atom, the alkoxy group, the acyloxy group, or the substituted or unsubstituted amino group. In the case in which the metal atom represented by M is a hafnium, zirconium or titanium atom, the hydrolyzable group represented by Y is preferably the halogen atom, the alkoxy group, or the acyloxy group.

The ligand which may be represented by I) is exemplified by a monodentate ligand and a polydentate ligand.

Exemplary monodentate ligands include a hydroxy ligand, a nitro ligand, ammonia, and the like.

Exemplary polydentate ligands include: a hydroxy acid ester, a P-diketone, a P-keto ester, a malonic acid diester which may he substituted at a carbon atom of a-position, and a hydrocarbon having a it bond; and ligands derived from these compounds; as well as diphosphine; and the like.

Examples of the diphosphine include 1,1-bis(diphenylphosphino)methane, 2-bis(diphenylphosphino)ethane, 1,3-bis(diphenylphosphino)propane, 2,2′-bis(diphenylphosphino)-1,1′-binaphth.yl, 1,1′-bis(diphenylphosphino)ferrocene, and the like.

The monovalent organic group which may be represented by is exemplified by groups similar to those exemplified as the monovalent organic group having 1 to 20 carbon atoms which may be represented by in the above formula (1), and the like. The lower limit of the number of carbon atoms of the monovalent organic group which may be represented by L¹ is preferably 2, and more preferably 3. On the other hand, the upper limit of the number of carbon atoms is preferably 10, and more preferably 5. The monovalent organic group which may be represented by L¹ is: preferably a substituted or unsubstituted hydrocarbon group; more preferably a substituted or unsubstituted chain hydrocarbon group, or a substituted or unsubstituted aromatic hydrocarbon group; still more preferably a substituted or unsubstituted alkyl group, or a substituted or unsubstituted aralkyl group; and particularly preferably an i-propyl group or a benzyl group.

al is preferably 1 or 2, and more preferably 1.

b1 is preferably an integer of 2 to 4. When bi falls within the above range, a proportion of the metal atom contained in the metal-containing compound (P) increases, whereby generation of the secondary electron by the metal-containing compound (P) can be effectively promoted. As a result, pattern collapse can be more certainly inhibited.

The metal compound (1) is preferably a halogenated metal compound, and more preferably iso-propyltin trichloride or benzyltin trichloride.

As a process for subjecting the metal compound (1) to a hydrolytic condensation reaction, for example, a process in which a mixture of the metal compound (1) in water or a solvent containing water is stirred in the presence of a base such as tetramethyl ammonium hydroxide which is used as needed, and the like, may be exemplified. In this case, an other compound having a hydrolyzable group may be added as needed. The lower limit of an amount of water used in the hydrolytic condensation reaction is, with respect to the hydrolyzable group included in the metal compound (1) and the like, preferably 0.2 times the molar amount, more preferably I time the molar amount, and still more preferably 3 times the molar amount. When the amount of water in the hydrolytic condensation reaction falls within the above range, the metal-containing compound (P) can be readily and certainly obtained.

Upon the synthesis reaction of the metal-containing compound (P), a compound that can be a bridging ligand, the polydentate ligand represented by L¹ in the compound represented by the above formula (4), etc., may be added, in addition to the metal compound (1). The compound that can be the bridging ligand is exemplified by a compound having at least two groups that can be coordinated, such as a hydroxy group, an isocyanate group, an amino group, an ester group, and/or an amide group, and the like.

The lower limit of a temperature of the synthesis reaction of the metal-containing compound (P) is preferably 0° C., and more preferably 10° C. The upper limit of the temperature is preferably 150° C., more preferably 100° C., and still more preferably 50° C.

The lower limit of a time period of the synthesis reaction of the metal-containing compound (P) is preferably I min, more preferably 10 min, and still more preferably 1 hour. The upper limit of the time period is preferably 100 hrs, more preferably 50 hrs, still more preferably 24 hrs, and particularly preferably 4 hrs.

(Q) Solvent

As the solvent (Q), an organic solvent is preferred. Specific examples of the organic solvent include organic solvents similar to those exemplified as the solvent (B) in the composition for resist underlayer film formation described above, and the like.

The solvent (Q) is preferably an alcohol solvent, more preferably a monohydric alcohol solvent, and still more preferably 4-meth 1-2-pentanol.

Other Optional Component(s)

The composition for metal-containing resist film formation may contain, in addition to the metal-containing compound (P) and the solvent (Q), other optional component(s) such as a surfactant and a compound that can be a ligand.

Compound that can be Ligand

The compound that can be a ligand is exemplified by a compound that can be a polydentate ligand or a bridging ligand, and the like, and specific examples include compounds that can be a polydentate ligand or a bridging ligand similar to those exemplified in the procedure of synthesizing the metal-containing compound (P), and the like.

Surfactant

The surfactant is a component that exhibits the effect of improving coating properties, striation and the like. Examples of the surfactant include: nonionic surfactants such as polyoxyethylene lauryl ether, polyoxyethylene stearyl ether, polyoxyethylene ( )ey' ether, polyoxyethylene n-octylphenyl ether, polyoxyethylene n-nonylphenyl ether, polyethylene glycol dilaurate, and polyethylene glycol distearate; as well as those having trade names of KP341 (available from Shin-Etsu Chemical Co., Ltd.), Polyflow No. 75 and Polyflow No. 95 (each available from Kyoeisha Chemical Co., Ltd.), EFTOP EF301 EFTOP EF303, and EFTOP EF352 (each available from Tochem Products Co., Ltd. (currenty, Mitsubishi Materials Electronic Chemicals Co., Ltd.)), Megaface F171 and Megaface F173 (each available from Dainippon Ink And Chemicals, Incorporated), Fluorad FC430 and Fluorad FC431 (each available from Sumitomo 3M Limited), ASAHI GUARD AGTIO, Surflon S-382, Surflon SC-101, Surflon SC-102, Surflon SC-103, Surflon SC-104, Surflon SC-1.05, and Surflon SC-106 (each available from Asahi Glass Co., Ltd.), and the like.

Preparation procedure of composition for metal-containing resist film formation

The composition for metal-containing resist film formation which may be a radiation-sensitive composition for resist film formation can be prepared, for example, by mixing at a certain ratio, the metal-containing compound (p), and as needed, the other optional component(s) such as the solvent (Q), preferably followed by filtering a thus obtained mixture through a membrane filter having a pore size of about 0.2 μm. In the case in which the composition for metal-containing resist film formation contains the solvent (Q), the lower limit of the solid content concentration of the composition for metal-containing resist film formation is preferably 0.1% by mass, more preferably 0.5% by mass, still more preferably 1% by mass, and particularly preferabl 2% by mass. On the other hand, the upper limit of the solid content concentration is preferably 50% by mass, more preferably 30% by mass, still more preferably 15% by mass, and particularly preferably 4% by mass.

Exposing Step

In this step, the metal-containing resist film formed by the composition for metal-containing resist film formation-applying step is exposed to an electron beam or extreme ultraviolet ray (wavelength: 13.5 nm or the like; “EUV”). Specifically, for example, the metal-containing resist film is irradiated with an electron beam or extreme ultraviolet ray through a mask having a predetermined pattern. By this step, a difference in solubility in a developer solution is created between light-exposed regions and light-unexposed regions of the metal-containing resist film. Exposure conditions may be appropriately predetermined in accordance with the type and the like of the composition for metal-containing resist film formation employed.

In this step, post exposure baking (hereinafter, may be also referred to as “PEB”) may be carried out after the exposure for the purpose of improving types of performance of the metal-containing resist film such as a resolution, a pattern profile, and developability. A PEB temperature and a PEB time period may be appropriately predetermined in accordance with the type and the like of the composition for metal-containing resist film formation employed. The lower limit of the PEB temperature is preferably 50° C., and more preferably 70° C. The upper limit of the PEB temperature is preferably 200° C., and more preferably 150° C. The lower limit of the PEB time period is preferably 10 sec, and more preferably 30 sec. The upper limit of the PEB time period is preferably 600 sec, and more preferably 300 sec.

Development Step

In this step, the metal-containing resist film exposed is developed. A developer solution used in the development is exemplified by an aqueous alkali solution (alkaline developer solution), an organic solvent-containing liquid (organic solvent developer solution), and the like. For example, in the positive-tone case in which the alkaline developer solution is used, due to an increase in solubility of light-exposed regions of the metal-containing resist film into the aqueous alkali solution, the light-exposed regions are removed by carrying out the development with an alkali, whereby the positive-tone resist pattern is formed. Alternatively, in the negative-tone case in which the organic solvent developer solution is used, due to a decrease in solubility of the light-exposed regions of the metal-containing resist film into the organic solvent, the negative-tone resist pattern is formed by removing regions unexposed with light, which have relatively higher solubility in the organic solvent, through carrying out the development with the organic solvent.

Examples of the aqueous alkali solution (alkaline developer solution) include alkaline aqueous solutions prepared by dissolving at least one type of alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, meth ldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene, and the like.

The lower limit of a proportion of the alkaline compound contained in the aqueous alkali solution is preferably 0.1% by mass, more preferably 0.5% by mass, and still more preferably 1% by mass. The upper limit of the proportion is preferably 20% by mass, more preferably 10% by mass, and still more preferably 5% by mass.

The aqueous alkali solution is preferably an aqueous TMAH solution, and more preferably a 2.38% by mass aqueous TMAH solution.

As the organic solvent contained in the organic solvent-containing liquid (organic solvent developer solution), a well-known organic solvent which may be used in the development with an organic solvent can be employed. For example, an organic solvent similar to those exemplified above as the solvent (B) in the composition for metal-containing resist film formation, or the like may be employed.

The organic solvent is preferably the ester solvent, the ether solvent, the alcohol solvent, the ketone solvent and/or the hydrocarbon solvent, more preferably the ketone solvent, and particularly preferably 2-heptanone.

The lower limit of a proportion of the organic solvent contained in the organic solvent-containing liquid is preferably 80% by mass, more preferably 90% by mass, still more preferably 95% by mass, and particularly preferably 99% by mass.

These developer solutions may be used either alone of one type, or in a combination of two or more types. It is to be noted that the development is typically followed by washing and drying.

Etching Step

In this step, etching is carried out using the resist pattern or the like as a mask. The etching may be conducted once or multiple times. In other words, the etching may be conducted sequentially with patterns obtained by the etching as masks. However, in light of obtaining a pattern having a more favorable configuration, the etching is preferably conducted multiple times. In the case in which the etching is conducted multiple times, for example, in the case of the organic underlayer film being absent, the resist underlayer film and the substrate are subjected to the etching sequentially in this order, whereas in the case of organic underlayer film being present, the resist underlayer film, the organic underlayer and the substrate are subjected to the etching sequentially in this order. An etching procedure may be exemplified by dry etching, wet etching, and the like. Of these, in light of the configuration of the substrate pattern to be formed being more favorable, the dry etching is preferred. As an etching gas, a fluorine-based gas, an oxygen-based gas, or the like may be appropriately selected in accordance with a material of the mask and a layer to be etched. For example, in dry etching of a resist underlayer film (silicon-containing film) conducted using a resist pattern as a mask, the fluorine-based gas is typically used, and a mixture of the fluorine-based gas with the oxygen-based gas and an inert gas may be suitably used. In dry etching of an organic underlayer film conducted using a resist underlayer film (silicon-containing film) pattern as a mask, the oxygen-based gas is typically used. In dry etching of a substrate conducted using an organic underlayer film pattern as a mask, a gas similar to that for the dry etching of the resist underlayer film (silicon-containing film), or the like may be used. After the etching, a patterned substrate having the predetel mined pattern is obtained.

### EXAMPLES

Hereinafter, Examples are described. It is to be noted that the following Examples merely illustrate typical Examples of the embodiments of the present invention, and the Examples should not be construed to narrow the scope of the present invention.

In the present Examples, measurement of a weight average molecular weight (Mw) of the compound (A), measurement of a concentration of the compound (A) in each solution, and measurement of an average thickness of each film were carried out by the following methods, respectively.

Measurement of Weight Average Molecular Weight (Mw)

Measurement of the weight average molecular weight (Mw) of the compound (A) was carried out by gel permeation chromatography (GPC) by using GPC columns (“G2000 HXL”×2, “G3000 HXL”×1, and “G4000 HXL”×1, all available from Tosoh Corporation) under the following conditions.

elution solvent: tetrahydrofuran

flow rate: 1.0 mL/min

sample concentration: 1.0% by mass

amount of injected sample: 100 uL

column temperature: 40° C.

detector: differential refractometer

standard substance: mono-dispersed polystyrene

Concentration of Compound (A) in Solution

The concentration (unit: % by mass) of the compound (A) in the solution was determined by: baking 0.5 g of the solution of the compound (A) at 250° C. for 30 min; measuring a mass of a residue thus obtained; and dividing the mass of the residue by the mass of the solution of the compound (A).

Average Thickness of Film

The average thickness of the film was measured by using a spectroscopic ellipsometer (“M2000D,” available from J. A. Woollam Co.).

### Synthesis of Compound (A)

Monomers (hereinafter, may be also referred to as “monomers (M-1) to (M-13)”) used for synthesis of the compound (A) are presented below. In the following Synthesis Examples, Comparative Synthesis Examples, and Reference Synthesis Examples, unless otherwise specified particularly, “parts by mass” mean a value, provided that the total mass of the monomer used corresponds to 100 parts by mass, and “mol %” mean a value, provided that the total number of moles of the monomer used corresponds to 100 mol %.

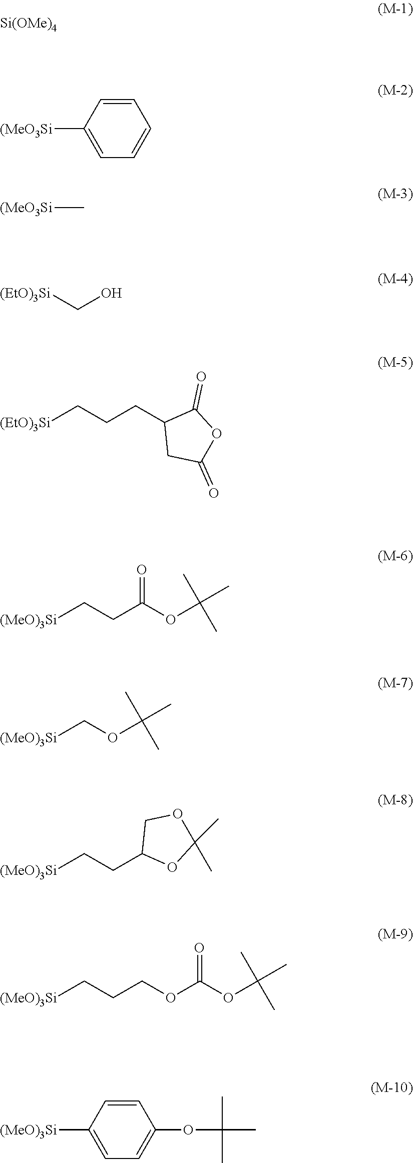

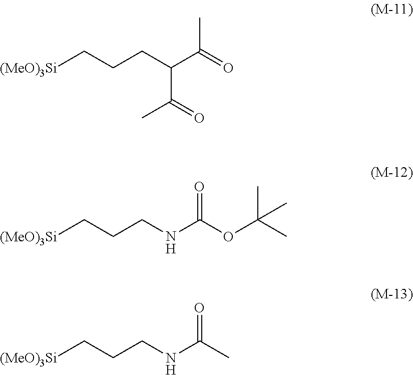

### Synthesis Example 1

### Synthesis of Compound (A-1)

In a reaction vessel, a monomer solution was prepared by dissolving in 53 parts by mass of propylene glycol monoethyl ether, the monomer (M-1) and the monomer (M-4) (100 parts by mass in total) such that the molar ratio became 90/10 (by mol %). The internal temperature of the reaction vessel was adjusted to 5° C., and 49 parts by mass of a 9.1% by mass aqueous oxalic acid solution were added dropwise over 20 min with stirring. After completion of the dropwise addition, the interior of the reaction vessel was heated to 40° C. and the reaction was performed for 4 hrs. After completion of the reaction, 98 parts by mass of water were added thereto and the mixture was stirred for 1 hour. After completion of the stirring, the internal temperature of the reaction vessel was lowered to no greater than 30° C. To a thus cooled reaction solution, 375 parts by mass of propylene glycol monoethyl ether were added. Thereafter, water, alcohols generated by the reaction, and excess propylene glycol monoethyl ether were removed by using an evaporator to give a propylene glycol monoethyl ether solution of the compound (A-1). The Mw of the compound (A-1) was 1,800. The concentration of the compound (A-1) in the propylene glycol monoethyl ether solution was 10.0% by mass.

### Synthesis Examples 2 to 12 and Comparative Synthesis Examples 1 to 2

### Synthesis of Compounds (A-2) to (A-12) and Compounds (a-1) to (a-2)

Propylene glycol monoethyl ether solutions of compounds (A-2) to (A-12) and compounds (a-1) to (a-2) were obtained in a similar manner to Synthesis Example 1 except that each monomer of the type and in the amount (mol %) shown in Table 1 below was used. The Mw of the compound (A) obtained and the concentration (% by mass) of the compound (A) in the propylene glycol monoethyl ether solution are shown together in Table 1 below. In Table 1 below, “-” indicates that the corresponding monomer was not used.

TABLE 1

| | | | | | | | | | | | | | | | | Concentration |
|---|---|---|---|---|---|---|---|---|---|---|---|---|---|---|---|---|
| | | | | | | | | | | | | | | | | of (A) |
| | | | | | | | | | | | | | | | | compound |
| | (A) | Amount of each monomer charged (mol %) | | | | | | | | | | | | | | in solution |
| | Compound | M-1 | M-2 | M-3 | M-4 | M-5 | M-6 | M-7 | M-8 | M-9 | M-10 | M-11 | M-12 | M-13 | Mw | (% by mass) |
| Synthesis | A-1 | 90 | — | — | 10 | — | — | — | — | — | — | — | — | — | 1,800 | 10.0 |
| Example 1 | | | | | | | | | | | | | | | | |
| Synthesis | A-2 | 80 | 10 | — | 10 | — | — | — | — | — | — | — | — | — | 1,900 | 10.0 |
| Example 2 | | | | | | | | | | | | | | | | |
| Synthesis | A-3 | 80 | — | 10 | 10 | — | — | — | — | — | — | — | — | — | 1,700 | 10.0 |
| Example 3 | | | | | | | | | | | | | | | | |
| Synthesis | A-4 | 90 | — | — | — | 10 | — | — | — | — | — | — | — | — | 2,000 | 10.0 |
| Example 4 | | | | | | | | | | | | | | | | |
| Synthesis | A-5 | 90 | — | — | — | — | 10 | — | — | — | — | — | — | — | 2,200 | 10.0 |
| Example 5 | | | | | | | | | | | | | | | | |
| Synthesis | A-6 | 90 | — | — | — | — | — | 10 | — | — | — | — | — | — | 1,900 | 10.0 |
| Example 6 | | | | | | | | | | | | | | | | |
| Synthesis | A-7 | 90 | — | — | — | — | — | — | 10 | — | — | — | — | — | 1,600 | 10.0 |
| Example 7 | | | | | | | | | | | | | | | | |
| Synthesis | A-8 | 90 | — | — | — | — | — | — | — | 10 | — | — | — | — | 2,300 | 10.0 |
| Example 8 | | | | | | | | | | | | | | | | |
| Synthesis | A-9 | 90 | — | — | — | — | — | — | — | — | 10 | — | — | — | 1,900 | 10.0 |
| Example 9 | | | | | | | | | | | | | | | | |
| Synthesis | A-10 | 90 | — | — | — | — | — | — | — | — | — | 10 | — | — | 1,900 | 10.0 |
| Example 10 | | | | | | | | | | | | | | | | |
| Synthesis | A-11 | 90 | — | — | — | — | — | — | — | — | — | — | 10 | — | 2,100 | 10.0 |
| Example 11 | | | | | | | | | | | | | | | | |
| Synthesis | A-12 | 90 | — | — | — | — | — | — | — | — | — | — | — | 10 | 2,000 | 10.0 |
| Example 12 | | | | | | | | | | | | | | | | |
| Comparative | a-1 | 80 | 20 | — | — | — | — | — | — | — | — | — | — | — | 2,000 | 10.0 |
| Synthesis | | | | | | | | | | | | | | | | |
| Example 1 | | | | | | | | | | | | | | | | |
| Comparative | a-2 | 80 | — | 20 | — | — | — | — | — | — | — | — | — | — | 1,900 | 10.0 |
| Synthesis | | | | | | | | | | | | | | | | |
| Example 2 | | | | | | | | | | | | | | | | |

### Reference Synthesis Example 1

### Synthesis of Compound (a-3)

Into a nitrogen-substituted reaction vessel, 18.61 parts by mass of magnesium and 35 parts by mass of tetrahydrofuran were charged, and the mixture was stirred at 20° C. Next, dibromomethane, trichloromethyisilane, and trichlorohydrosilane (100 parts by mass in total) were dissolved such that a molar ratio became 50/15/35 (moi% basis), in 355 parts by mass of tetrahydrofuran to prepare a monomer solution. The internal temperature of the reaction vessel was adjusted to 20° C., and the monomer solution was added dropwise thereto over I hr with stirring. A time point of completion of the dropwise addition was defined as a start time of the reaction, and the reaction was allowed at 40° C. for 1 hr, and then at 60° C. for 3 hrs. After completion of the reaction, 213 parts by mass of tetrahydrofuran were added thereto, and the mixture was cooled to no greater than 10° C. to give a polymerization reaction liquid. Next, 96.84 parts by mass of triethylamine were added to the polymerization reaction liquid, and then 30,66 parts by mass of methanol were added dropwise over 10 min with stirring. A time point of completion of the dropwise addition was defined as a start time of the reaction, and the reaction was allowed at 20° C. for 1 hour. The reaction liquid was charged into 700 parts by mass of diisopropyl ether, and a salt thus precipitated was filtered out. Next, tetrahydrofuran, excess triethylamine, and excess methanol in the filtrate were removed by using an evaporator. A thus resulting residue was charged into 180 parts by mass of diisopropyl ether, and a salt thus precipitated was filtered out. An addition of diisopropyl ether to the filtrate gave 223 g of a solution of polycarbosilane (aa-3) in diisopropyl ether. The Mw of the polycarbosilane (aa-3) was 700.

Into a reaction vessel, 100 parts by mass from 223 parts by mass of the solution of the polycarbosilane (aa-3) in diisopropyl ether, and 90 parts by mass of methanol were charged. The internal temperature of the reaction vessel was adjusted to 30° C., and 8 parts by mass of a 3.2% by mass aqueous oxalic acid solution were added dropwise thereto over 20 min with stirring. A time point of completion of the dropwise addition was defined as a start time of the reaction, and the reaction was allowed at 40° C. for 4 hrs, followed by cooling to adjust the internal temperature of the reaction vessel to no greater than 30° C. Next, to this reaction vessel were added 99 parts by mass of diisopropyl ether and 198 parts by mass of water, and liquid separation extraction was conducted. Thereafter, to an organic layer thus obtained were added 0.26 parts by mass of oxalic acid dihydrate and 396 parts by mass of propylene glycol monomethyl ether acetate. Then, water, diisopropyl ether, alcohols produced by the reaction, and excess propylene glycol monomethyl ether acetate were removed by using an evaporator. Next, to a solution thus obtained were added 19.82 parts by mass of trimethyl orthoformate as a dehydrating agent, and after the reaction was allowed at 40° C. for 1 hour, the internal temperature of the reaction vessel was adjusted to no greater than 30° C. by cooling. To the reaction vessel were added 99 parts by mass of propylene glycol monomethyl ether acetate, and then esters and alcohols produced by the reaction, trimethyl orthoformate, and excess propylene glycol monomethyl ether acetate were removed by using an evaporator to give a solution of the compound (a-3) in propylene glycol monomethyl ether acetate. The Mw of the compound (a-3) was 2,500. The concentration of the solution of the compound (a-3) in propylene glycol monomethyl ether acetate was 5% by mass.

### Reference Synthesis Example 2

### Synthesis of Compound (a-4)

A solution of the compound (a-4) in propylene glycol monomethyl ether acetate was obtained similarly to Reference Synthesis Example 1 described above except that dibromomethane, tetrachlorosilane, trichloromethylsilane, and trichlorohydrosilane (molar ratio: 50/5/15/30 (mol % basis), 100 parts by mass in total) were employed in place of dibromomethane, trichloromethylsilane, and trichlorohydrosilane (molar ratio: 50/15/35 (mol % basis), 100 parts by mass in total) in Reference Synthesis Example 1. The Mw of the compound (a-4) was 2,100. The concentration of the solution of the compound (a-4) in propylene glycol monomethyl ether acetate was 5% by mass.

### Preparation of Composition for Resist Underlayer Film Formation

The solvent (13) and the additive (C) used in preparing each composition for resist underlayer film formation are as shown below.

(B) Solvent

B-1: propylene glycol monoethyl ether

B-2: propylene glycol monomethyl ether acetate

(C) Additive

C-1: a compound represented by the following formula (C-1)

C-2: a compound represented by the fol lowing formula (C-2)

C-3: a compound represented by the following formula (C-3)

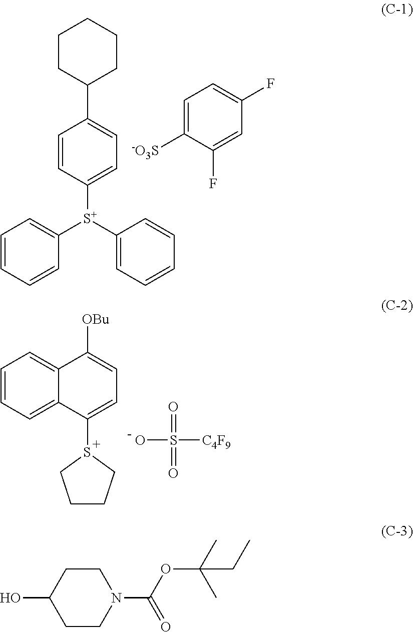

### Example 1-1

A composition for resist underlayer film formation (.1-1) was prepared by: mixing 0,5 parts by mass (not including the solvent) of (A-1) as the compound (A), and as the solvent (B), 95.5 parts by mass (including also (B-1) as the solvent contained in the solution of the compound (A)) of (B-1) and 4 parts by mass (including also water contained in the solution of the compound (A)) of water; and filtering a resulting solution through a PTFE (polytetrafluoroethylene) filter having a pore size of 0,2 p.m.

### Examples 1-2 to 1-14, Comparative Examples to 1-2, and. Reference Examples 1-1 to 1-2

Compositions (J-2) to (J-14) and (j-1) to (j-4) were prepared by a similar operation to that of Example 1 except that for each component, the type and the blended amount shown in Table 2 below were used. In Table 2 below, “-” indicates that the corresponding component was not used.

TABLE 2

| | | (A) | | (B) | | (C) | | |
|---|---|---|---|---|---|---|---|---|
| | Composition | Compound | | Solvent | | Additive | | Water |
| | for resist | | blended | | blended | | blended | blended |
| | underlayer | | amount | | amount | | amount | amount |
| | film | | (parts by | | (parts by | | (parts by | (parts by |
| | formation | type | mass) | type | mass) | type | mass) | mass) |
| Example 1-1 | J-1 | A-1 | 0.5 | B-1 | 95.5 | — | — | 4 |
| Example 1-2 | J-2 | A-2 | 0.5 | B-1 | 95.5 | — | — | 4 |
| Example 1-3 | J-3 | A-3 | 0.5 | B-1 | 95.5 | — | — | 4 |
| Example 1-4 | J-4 | A-4 | 0.5 | B-1 | 95.5 | — | — | 4 |
| Example 1-5 | J-5 | A-5 | 0.5 | B-1 | 95.5 | — | — | 4 |
| Example 1-6 | J-6 | A-6 | 0.5 | B-1 | 95.5 | — | — | 4 |
| Example 1-7 | J-7 | A-7 | 0.5 | B-1 | 95.5 | — | — | 4 |
| Example 1-8 | J-8 | A-8 | 0.5 | B-1 | 95.5 | — | — | 4 |
| Example 1-9 | J-9 | A-9 | 0.5 | B-1 | 95.5 | — | — | 4 |
| Example 1-10 | J-10 | A-10 | 0.5 | B-1 | 95.5 | — | — | 4 |
| Example 1-11 | J-11 | A-11 | 0.5 | B-1 | 95.5 | — | — | 4 |
| Example 1-12 | J-12 | A-12 | 0.5 | B-1 | 95.5 | — | — | 4 |
| Example 1-13 | J-13 | A-5 | 0.5 | B-1 | 95.5 | C-1 | 0.01 | 4 |
| Example 1-14 | J-14 | A-5 | 0.5 | B-1 | 95.5 | C-3 | 0.01 | 4 |
| Comparative | j-1 | a-1 | 0.5 | B-1 | 95.5 | — | — | 4 |
| Example 1-1 | | | | | | | | |
| Comparative | j-2 | a-2 | 0.5 | B-1 | 95.5 | — | — | 4 |
| Example 1-2 | | | | | | | | |
| Reference | j-3 | a-3 | 0.5 | B-2 | 99.5 | C-2 | 0.01 | — |
| Example 1-1 | | | | | | | | |
| Reference | j-4 | a-4 | 0.5 | B-2 | 99.5 | — | — | — |
| Example 1-2 | | | | | | | | |

Preparation of Composition for Metal-Containing e,i, Formation

Synthesis of Compounds

Compounds (S-1) to (S-4) used in preparing the composition for metal-containing resist film formation were synthesized according to the procedures described below.

### Synthesis Example 2-1

### Synthesis of Compound (S-1)

In a reaction vessel, while 150 mt. of a 0.5 N aqueous sodium hydroxide solution was stirred, 6.5 parts by mass of iso-propyltin trichloride were added, and a reaction was performed for 2 hrs. A precipitate thus produced was filtered out, and washed with 50 parts by mass of water and then dried to give a compound (S-1). The compound (S-1) was an oxidized and hydroxylated product (structural unit: i-PrSnO_{(3/2-x/2)}(OH)ₓ (0<x<3)) of a hydrolyzate of iso-propyltin trichloride,

### Synthesis Example 2-2

### Synthesis of Compound (S-2)

In a reaction vessel, while 100 mi., of a 0.5 M aqueous tetramethylammonium hydroxide solution was stirred, 3.16 parts by mass of benzyltin trichloride were added, and a reaction was performed for 2 hrs. A precipitate thus produced was filtered out, and washed with 50 parts by mass of water and then dried to give a compound (S-2). The compound (5-2) was a compound having a structural unit represented by ((PhCH₂)SnO_{3/2}).

### Synthesis Example 2-3

### Synthesis of Compound (S-3)

In a reaction vessel, 20.0 parts by mass of tetrabutoxytin(IV), 100 parts by mass of tetrahydrofuran, and 100 parts by mass of methacrylic acid were charged, and a reaction was performed at 65° C. for 20 min. Next, 10.6 parts by mass of water were added dropwise over 10 min, and a reaction was performed at 65° C. for 18 hrs. Subsequently, 10.6 parts by mass of water were added dropwise over 10 min, and the mixture was stirred for 2 hrs. To a cooled reaction liquid, 400 parts by mass of water were added to give a precipitate. The precipitate thus obtained was subjected to centrifugal separation, and thereafter dissolved in 50 parts by mass of acetone, to which 400 parts by mass of water were added to give a precipitate. The precipitate thus obtained was subjected to centrifugal separation, and thereafter dried to give a compound (S-3), The compound (S-3) was particles containing a metal oxide of tin as a principal component, and also containing methacrylic acid.

### Synthesis Example 2-4

### Synthesis of Compound (S-4)

In a reaction vessel, 20.0 parts by mass of tetraisopropoxyzirconium(W), 100 parts by mass of tetrahydrofuran, and 100 parts by mass of methacrylic acid were charged, and a reaction was performed at 65° C. for 20 min. Next, 10.6 parts by mass of water were added dropwise over 10 min, and a reaction was performed at 65° C. for 18 hrs. Subsequently, 10.6 parts by mass of water were added dropwise over 10 min, and the mixture was stirred for 2 hrs. To a cooled reaction liquid, 400 parts by mass of water were added to give a precipitate. The precipitate thus obtained was subjected to centrifugal separation, and thereafter dissolved in 50 parts by mass of acetone, to which 400 parts by mass of water were added to give a precipitate. The precipitate thus obtained was subjected to centrifugal separation, and thereafter dried to give a compound (S-4). The compound (S-4) was particles containing a metal oxide of zirconium as a principal component, and also containing methacrylic acid.

Preparation of Composition for Metal-Containing Resist Formation

### Preparation Example 2-1

A composition for metal-containing resist film formation (K-1) was prepared by: mixing 2 parts by mass of the compound (S-1) synthesized as described above, and 98 parts by mass of propylene glycol monoethyl ether; using a 4 A activated molecular sieve to remove residual water from a mixture thus obtained; and then filtering a resulting solution through a filter having a pore size of 0.2 μm.

### Preparation Example 2-2

A composition for metal-containing resist film formation (K-2) was prepared by: mixing 2 parts by mass of the compound (S-2) synthesized as described above, and 98 parts by mass of propylene glycol monoethyl ether; and filtering a resulting solution through a filter having a pore size of 0.2 μm.

### Preparation Example 2-3

A composition for metal-containing resist film formation (K-3) was prepared by: mixing 2 parts by mass of the compound (S-3) synthesized as described above, 98 parts by mass of propylene glycol monoethyl ether, and 0.2 parts by mass of N-trifluoromethanesulfonyloxy-5-norbornene-2,3-dicarboxyimide; and filtering a resulting solution through a filter having a pore size of 0.2 μm.

### Preparation Example 2-4

A composition for metal-containing resist film formation (K-4) was prepared by: mixing 2 parts by mass of the compound (S-4) synthesized as described above, 98 parts by mass of propylene glycol monoethyl ether, and 0.2 parts by mass of N-trifluoromethanesulfonyloxy-5-norbornene-2,3-dicarboxyimide; and filtering a resulting solution through a filter having a pore size of 0.2 μm.

### Evaluation

### Examples 2-1 to 2-29, Comparative Examples 2-1 to 2-8, and Reference Examples 1-1 to 1-2

Using each composition for resist underlayer film formation prepared, and each composition for metal-containing resist film formation prepared, a resist pattern collapse-inhibiting property was evaluated by the following method. The results of the evaluation are shown in Table 3 below.

Resist Pattern Collapse-Inhibiting Property

A material for organic underlayer film formation (“HM8006,” available from JSR Corporation) was applied on a 12-inch silicon wafer by spin-coating using a spin-coater (“CLEAN TRACK ACT 12,” available from Tokyo Electron Limited), and thereafter heating was conducted at 250° C. for 60 sec to form an organic underlayer film having an average thickness of 100 nm. Each composition for resist underlayer film formation prepared as described above was applied on the organic underlayer film, and subjected to heating at 220° C. for 60 sec, followed by cooling at 23° C. for 30 sec to form a resist underlayer film having an average thickness of 10 nm. The composition for metal-containing resist film formation shown in Table 3 below was applied on this resist underlayer film by spin-coating using the above-mentioned spin-coater. After a certain time period had passed, heating was conducted at 90° C. for 60 sec, followed by cooling at 23° C. for 30 sec to forcrr a metal-containing resist film having an average thickness of 35 nm. The metal-containing resist film was subjected to exposure by using an UN scanner (“TWINSCAN NXE: 3300B,” available from ASML Co.; (NA =0.3; Sigma =0.9; quadrupole illumination, with a 1:1 line-and-space pattern mask having a line width of 25 nm in terms of a dimension on wafer). After the exposure, the substrate was heated at 110° C. for 60 sec, followed by cooling at 23° C. for 60 sec. Thereafter, a development was carried out by using 2-heptanone (20 to 25° C.) with a puddle method, followed by drying to give a substrate for evaluation having a resist pattern formed thereon. For line-width measurement and observation of the resist pattern on the substrate for evaluation, a scanning electron microscope (“CG-6300,” available from Hitachi High-Tech Corporation) was used.

The resist pattern collapse-inhibiting property was evaluated to be:

“A” (extremely favorable) in a case of resist pattern collapse of lines with a line width of 18 nm not being confirmed;

“B” (favorable) in a case of resist pattern collapse of lines with a line width of 18 nm being confirmed, but resist pattern collapse of lines with a line width of 24 nm not being confi rm ed; or

“C” (unfavorable) in a case of resist pattern collapse of lines with a line idth of 24 nm being confirmed.

TABLE 3

| | Composition | Composition for | Resist pattern |
|---|---|---|---|
| | for resist | metal-containing | collapse- |
| | underlayer film | resist film | inhibiting |
| | formation | formation | property |
| Example 2-1 | J-1 | K-1 | A |
| Example 2-2 | J-2 | K-1 | A |
| Example 2-3 | J-3 | K-1 | A |
| Example 2-4 | J-4 | K-1 | A |
| Example 2-5 | J-5 | K-1 | A |
| Example 2-6 | J-6 | K-1 | A |
| Example 2-7 | J-7 | K-1 | A |
| Example 2-8 | J-8 | K-1 | A |
| Example 2-9 | J-9 | K-1 | A |
| Example 2-10 | J-10 | K-1 | A |
| Example 2-11 | J-11 | K-1 | A |
| Example 2-12 | J-12 | K-1 | B |
| Example 2-13 | J-13 | K-1 | B |
| Example 2-14 | J-14 | K-1 | B |
| Example 2-15 | J-1 | K-2 | A |
| Example 2-16 | J-4 | K-2 | A |
| Example 2-17 | J-5 | K-2 | A |
| Example 2-18 | J-6 | K-2 | A |
| Example 2-19 | J-11 | K-2 | A |
| Example 2-20 | J-1 | K-3 | A |
| Example 2-21 | J-4 | K-3 | A |
| Example 2-22 | J-5 | K-3 | A |
| Example 2-23 | J-6 | K-3 | A |
| Example 2-24 | J-11 | K-3 | A |
| Example 2-25 | J-1 | K-4 | A |
| Example 2-26 | J-4 | K-4 | A |
| Example 2-27 | J-5 | K-4 | A |
| Example 2-28 | J-6 | K-4 | A |
| Example 2-29 | J-11 | K-4 | A |
| Comparative | j-1 | K-1 | C |
| Example 2-1 | | | |
| Comparative | j-1 | K-2 | C |
| Example 2-2 | | | |
| Comparative | j-1 | K-3 | C |
| Example 2-3 | | | |
| Comparative | j-1 | K-4 | C |
| Example 2-4 | | | |
| Comparative | j-2 | K-1 | C |
| Example 2-5 | | | |
| Comparative | j-2 | K-2 | C |
| Example 2-6 | | | |
| Comparative | j-2 | K-3 | C |
| Example 2-7 | | | |
| Comparative | j-2 | K-4 | C |
| Example 2-8 | | | |
| Reference | j-3 | K-1 | C |
| Example 2-1 | | | |
| Reference | j-4 | K-1 | C |
| Example 2-2 | | | |

As is clear from the results shown in Table 3 above, each of the compositions for resist underlayer film formation of Examples was favorable in the resist pattern collapse-inhibiting property.

The composition for resist underlayer film fou nation of the one embodiment of the present invention can be suitably used in manufacturing a semiconductor substrate, and the like.

Obviously, numerous modifications and variations of the present invention(s) are possible in light of the above teachings. It is therefore to be understood that within the scope of the appended claims, the invention may be practiced otherwise than as specifrcal described herein.

What is claimed is:

1. A composition for resist underlayer film formation, comprising:
a polysiloxane compound comprising a first structural unit represented by formula (1); and
a solvent, 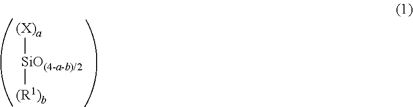
wherein, in the formula (1), X represents an organic group comprising at least one structure selected from the group consisting of a hydroxy group, a carbonyl group, and an ether bond; a is an integer of 1 to 3, wherein in a case in which a is no R¹ss than 2, a plurality of Xs are identical or different from each other; R¹ represents a halogen atom, a hydroxy group, or a monovalent organic group having 1 to 20 carbon atoms, wherein R¹ is a group other than X; and b is an integer of 0 to 2, wherein in a case in which b is 2, two R¹s are identical or different from each other, and wherein a sum of a and b is no greater than 3.

2. The composition according to claim 1, wherein the polysiloxane compound further comprises a second structural unit represented by formula (2): 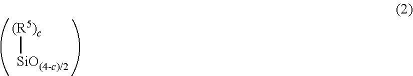
wherein, in the formula (2), R⁵ represents a halogen atom, a hydroxy group, or a substituted or unsubstituted monovalent alkoxy group having 1 to 20 carbon atoms; and c is an integer of 0 to 3, wherein in a case in which c is no R¹ss than 2, a plurality of R⁵s are identical or different.

3. The composition according to claim 1, wherein a proportion of the first structural unit with respect to total structural units constituting the polysiloxane compound is no R¹ss than 1 mol % and no greater than 40 mol %.

4. The composition according to claim 1, wherein the composition is suitable for forming an underlayer film of a metal-containing resist film in lithography with an electron beam or an extreme ultraviolet ray.

5. A method of producing a semiconductor substrate, the method comprising:
applying a composition for resist underlayer film formation directly or indirectly on a substrate to form a resist underlayer film;
applying a composition for metal-containing resist film formation on the resist underlayer film to forcrr a metal-containing resist film;
exposing the metal-containing resist film to an electron beam or an extreme ultraviolet ray; and
developing the metal-containing resist film exposed,
wherein the composition for resist underlayer film formation comprises:
a polysiloxane compound comprising a first structural unit represented by formula (1); and
a solvent, 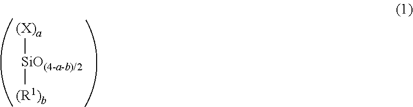
wherein, in the formula (1), X represents an organic group comprising at least one structure selected from the group consisting of a hydroxy group, a carbonyl group, and an ether bond; a is an integer of 1 to 3, wherein in a case in which a is no R¹ss than 2, a plurality of Xs are identical or different from each other; R¹ represents a halogen atom, a hydroxy group, or a monovalent organic group having 1 to 20 carbon atoms, wherein R¹ is a group other than X; and b is an integer of 0 to 2, wherein in a case in which b is 2, tA R¹s are identical or different from each other, and wherein a sum of a and b is no greater

6. The method according to claim 5, further comprising, before the applying of the composition for resist underlayer film formation_{;}
forming an organic underlayer film directly or indirectlyon the substrate.

7. The method according to claim 5, wherein the polysiloxane compound further comprises a second structural unit represented by formula (2): 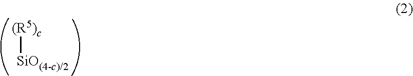
wherein, in the formula (2), R⁵ represents a halogen atom, a hydroxy group, or a substituted or unsubstituted monovalent alkoxy group having 1 to 20 carbon atoms; and c is an integer of 0 to 3, wherein in a case in which c is no R¹ss than 2, a plurality of R⁵s are identical or different.

8. The method according to claim 5, wherein a proportion of the first structural unit with respect to total structural units constituting the polysiloxane compound is no R¹ss than 1 mol % and no greater than 40 mol %.

9. The method according to claim 6, wherein the polysiloxane compound further comprises a second structural unit represented by formula (2): 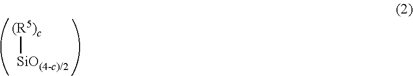
wherein, in the formula (2), R⁵ represents a halogen atom, a hydroxy group, or a substituted or unsubstituted monovalent alkoxy group having 1 to 20 carbon atoms; and c is an integer of 0 to 3, wherein in a case in which c is no R¹ss than 2, a plurality of R⁵s are identical or different.

10. The method according to claim 6, wherein a proportion of the first structural unit with respect to total structural units constituting the polysiloxane compound is no R¹ss than 1 mol % and no greater than 40 mol %.
